(19) United States
(12) Patent Application Publication
(10) Pub. No.: US 2017/0176792 A1
(43) Pub. Date: Jun. 22, 2017

(54) DISPLAY DEVICE

(71) Applicant: Japan Display Inc., Minato-ku (JP)

(72) Inventors: Daisuke SONODA, Tokyo (JP); Osamu ITOU, Tokyo (JP); Muneharu AKIYOSHI, Tokyo (JP)

(73) Assignee: Japan Display Inc., Minato-ku (JP)

(21) Appl. No.: 15/378,498

(22) Filed: Dec. 14, 2016

(30) Foreign Application Priority Data
Dec. 17, 2015 (JP) 2015-246123

(51) Int. Cl. G02F 1/1368; G02F 1/1343; G02F 1/1333; G02F 1/1362; H01L 27/12

(52) U.S. Cl. CPC G02F 1/1368; G02F 1/136209; H01L 27/1218; G02F 1/133345; G02F 1/136227; G02F 1/134336; G02F 1/136286; G02F 2001/136222; G02F 2001/13685; G02F 2001/134345; G02F 2201/123; G02F 2201/501

(57) ABSTRACT

According to one embodiment, a display device includes a color filter formed on an inorganic layer, an inorganic film formed above the color filter, and a semiconductor layer formed above the inorganic film. As seen in plan view, the inorganic film is provided over a first area in which the color filter is overlapped and a second area which surrounds the first area. In the second area, the inorganic film is located outward of the color filter.

### CROSS-REFERENCE TO RELATED APPLICATIONS

This application is based upon and claims the benefit of priority from Japanese Patent Application No. 2015-246123, filed Dec. 17, 2015, the entire contents of which are incorporated herein by reference.

### FIELD

Embodiments described herein relate generally to a display device.

### BACKGROUND

Liquid crystal display panels are light and thin, and their power consumptions are low. By virtue of these features, they are applied to various fields and for example, as display panels of office automation equipment such as personal computers and those of television receivers. In recent years, liquid crystal display panels have also been used as display panels of portable terminal devices such as cell phones, of car navigation equipment, and of game consoles, etc.

Also, each of the liquid crystal display panels comprises an array substrate, a counter-substrate and a liquid crystal layer held between these substrates. The array substrate is formed by repeatedly performing etching using film formation or a photolithography method. For example, there is a case where in the array substrate, a color filter is provided, and contact holes are formed in the color filter.

### BRIEF DESCRIPTION OF THE DRAWINGS

FIG. 1 is a perspective view illustrating a configuration of a liquid crystal display device according to an embodiment.

FIG. 2 is a cross-sectional view of a liquid crystal display panel as illustrated in FIG. 1.

FIG. 3 is an enlarged cross-sectional view illustrating part of the liquid crystal display panel as illustrated in FIGS. 1 and 2, and also a view illustrating a first insulating substrate, a color filter, an overcoat film and an inorganic film.

FIG. 4 is a plan view illustrating the first substrate as illustrated in FIGS. 1 to 3 and also a view illustrating the first insulating substrate, the color filter and the inorganic film.

FIG. 5 is a view illustrating an example of a pixel array in the liquid crystal display panel as illustrated in FIGS. 1 and 2.

FIG. 6 is a plan view illustrating a configuration of a first substrate as illustrated in FIGS. 1 to 4.

FIG. 7 is an enlarged plan view illustrating part of the first substrate, and illustrates scanning lines, signal lines, pixel switching elements, second electrodes, contact holes and pixel electrodes.

FIG. 8 is an enlarged plan view illustrating part of the first substrate, and also a view illustrating a light-shielding layer, scanning lines, signal lines, pixel switching elements, second electrodes and contact holes.

FIG. 9 is a cross-sectional view of the liquid crystal display panel which is taken along line IX-IX in FIG. 7.

FIG. 10 is a cross-sectional view of the liquid crystal display panel which is taken along line X-X in FIG. 7.

FIG. 11 is a cross-sectional view illustrating a modification of the liquid crystal display panel of the liquid crystal display device according to the embodiment.

### DETAILED DESCRIPTION

In general, according to one embodiment, there is provided a display device comprising: a color filter formed on an inorganic layer; an inorganic film formed above the color filter; and a semiconductor layer formed above the inorganic film. As seen in plan view, the inorganic film is provided over a first area in which the color filter is overlapped and a second area which surrounds the first area. In the second area, the inorganic film is located outward of the color filter.

An embodiment will be described hereinafter with reference to the accompanying drawings. The disclosure is a mere example, and arbitrary change of gist which can be easily conceived by a person of ordinary skill in the art naturally falls within the inventive scope. To better clarify the explanations, the drawings may pictorially show width, thickness, shape, etc., of each portion as compared with an actual aspect, but they are mere examples and do not restrict the interpretation of the invention. In the present specification and drawings, after structural elements are each explained once with reference to the drawings, there is a case where their explanations will be omitted as appropriate, and those identical to or similar to the explained structural elements will be denoted by the same reference numbers, respectively, as the explained structural elements.

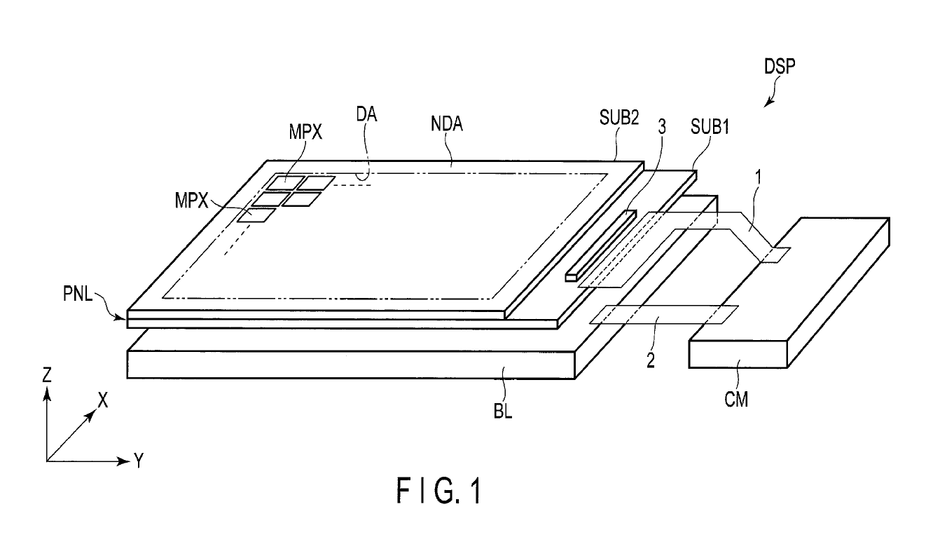

FIG. 1 is a perspective view illustrating a configuration of a liquid crystal display device DSP according to an embodiment. In the embodiment, a first direction X and a second direction Y are perpendicular to each other; however, they may intersect each other at an angle other than 90°. Also, a third direction Z is perpendicular to each of the first direction X and the second direction Y.

The liquid crystal display device DSP as display device comprises an active-matrix liquid crystal display panel PNL, a driver 3 which drives the liquid crystal display panel PNL, a backlight unit BL which illuminates the liquid crystal display panel PNL, a control module CM, flexible printed circuits 1 and 2, etc.

The liquid crystal display panel PNL comprises a first substrate SUB1 and a second substrate SUB 2 located opposite to the first substrate SUB1. Also, in the embodiment, the first substrate SUB1 functions as an array substrate, and the second substrate SUB2 functions as a counter-substrate. The liquid crystal display panel PNL includes a display area DA which displays an image and a non-display area NDA which is formed in the shape of a frame in such a way as to surround the display area DA. The liquid crystal display panel PNL comprises a plurality of main pixels MPX arranged in a matrix in the first direction X and the second direction Y in the display area DA. Each of the main pixels MPX corresponds to a group of three sub-pixels to be described later.

The backlight unit BL is provided on a rear surface of the first substrate SUB1. As the structure of the backlight unit BL, various structures can be applied. However, a detailed explanation of the structure of the backlight unit BL will be omitted. The driver 3 is mounted on the first substrate SUB1. The flexible printed circuit 1 connects the liquid crystal display panel PNL and the control module CM to each other. The flexible printed circuit 2 connects the backlight unit BL and the control module CM to each other.

The liquid crystal display device DSP having the above structure is a so-called transmissive liquid crystal display device in which sub-pixels are selectively caused to transmit therethrough light incident from the backlight unit BL on the liquid crystal display panel PNL to display an image.

In the following explanation, it is assumed that a direction from the first substrate SUB1 toward the second substrate SUB2 is an upward direction, and a direction from the second substrate SUB2 toward the first substrate SUB1 is a downward direction. Thus, the third direction Z is the upward direction. Furthermore, in the following, the phrases “formed above”, “located above”, and “formed below” are present, and for example, in descriptions and recitations disclosing that element I is formed above or below element II, they suggest that element I is separated from element II; however, element I may be in contact with element II. Also, in structural features disclosed in the above descriptions and recitations, element III may be interposed between elements I and II. Also, in the following, the phrases “formed on”, “located on”, “formed under” and “located under” are present, and for example, in descriptions and recitations disclosing that element I is formed on or under element II, they suggest that element I is in contact with element II. Also, in the explanation of the embodiment, the phrase “as seen in plan view” means viewing from an upper position than the second substrate SUB2 toward the first substrate SUB1.

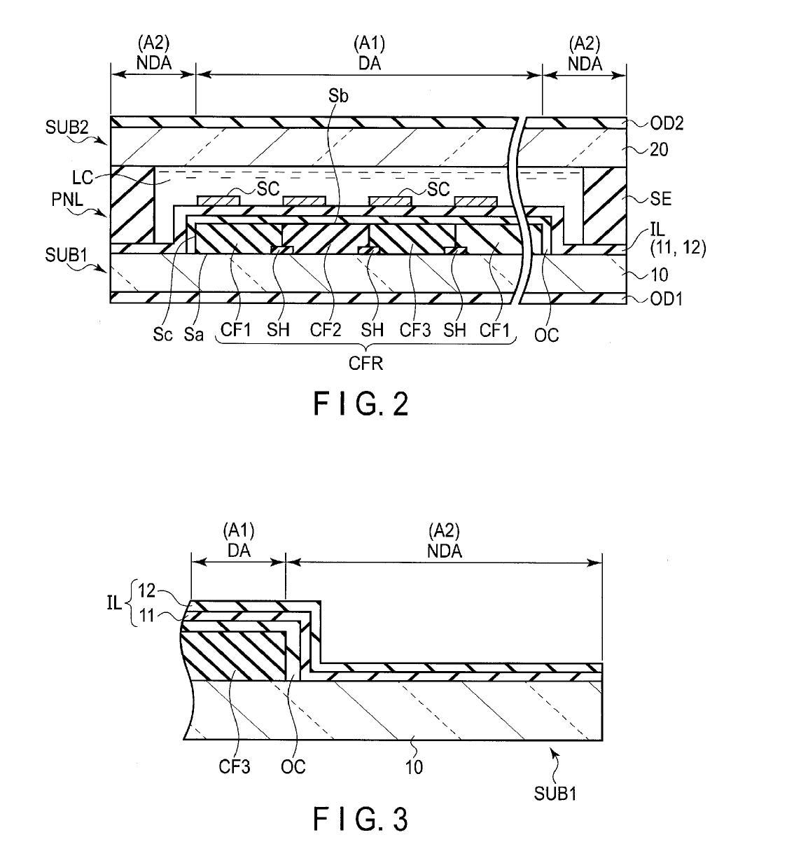

FIG. 2 is a cross-sectional view illustrating the liquid crystal display panel PNL.

As illustrated in FIG. 2, the liquid crystal display panel PNL comprises the first substrate SUB1, the second substrate SUB2, a liquid crystal layer LC, a sealing member SE, a first optical element OD1, a second optical element OD2, etc. The second substrate SUB2 is located above the first substrate SUB1 and separated therefrom by a predetermined distance such that they are opposite to each other. The liquid crystal layer LC is held between the first substrate SUB1 and the second substrate SUB2. The first substrate SUB1 and the second substrate SUB2 will be described later in detail, and the following explanation is given with respect to part of the first substrate SUB 1.

The first substrate SUB1 includes a first insulating substrate 10, a color filter CFR, an overcoat film OC, an inorganic film IL, semiconductor layers SC, etc.

The first insulating substrate 10 is located under the color filter CFR. The first insulating substrate 10 is formed of a transparent insulating material, for example, a glass such as borosilicate glass which is an inorganic material. In the embodiment, the first insulating substrate 10 is a glass substrate formed of a glass. An upper surface of the first insulating substrate 10 functions as an upper surface of an inorganic layer.

The color filter CFR is formed on the first insulating substrate 10. The color filter CFR is provided in the display area DA. In the embodiment, as seen in plan view, an area in which the color filter CFR is overlapped will be referred to as a first area A1, and an area surrounding the first area A1 will be referred to as a second area A2. The first area A1 substantially corresponds to the display area DA, and the second area A2 substantially corresponds to the non-display area NDA.

The color filter CFR includes a light-shielding layer SH and a plurality of colored layers CF1, CF2 and CF3. In the color filter CFR, for example, the colored layers CF1 have a first color, the colored layers CF2 have a second color and the colored layers CF3 have a third color. Adjacent portions between the colored layers CF1 and the colored layers CF2, those between the colored layer CF2 and the colored layer CF3 and those between the colored layers CF3 and the colored layers CF1 are located on the light-shielding layer SH.

In the following, it is assumed that a surface of the color filter CFR which contacts the first insulating substrate 10 is a bottom surface Sa, a surface of the color filter CFR which is located opposite to the bottom surface Sa is an upper surface Sb, and a surface of the color filter CFR which extends along the outline thereof as seen in plan view is an outer peripheral surface Sc.

The overcoat film OC is provided on the color filter CFR. The overcoat film OC is formed of an organic insulating material. It suffices that the overcoat film OC is provided as occasion arises. In the case of applying the overcoat film OC, it suffices that the overcoat film OC is provided at least on the upper surface Sb of the color filter CFR. In the embodiment, the overcoat film OC is in contact with the entire upper surface Sb and the entire outer peripheral surface Sc of the color filter CFR, and covers the entire color filter CFR.

The inorganic film IL is formed above the first insulating substrate 10, the color filter CFR and the overcoat film OC. In the embodiment, the inorganic film IL is in contact with the entire surface of the overcoat film OC, and also in the second area A2 (non-display area NDA), the inorganic film IL is formed on the upper surface of the first insulating substrate 10 and around the first area A1. Also, in the second area A2, the inorganic film IL is located outward of the color filter CFR. Furthermore, in the second area A2 (non-display area NDA), the inorganic film IL is formed on the upper surface of the first insulating substrate 10 with no space between them and around the first area A1. The inorganic film IL covers the upper surface Sb and the outer peripheral surface Sc of the color filter CFR.

The semiconductor layers SC are formed above the inorganic film IL. In the embodiment, the semiconductor layers SC are formed on the inorganic film IL.

The sealing member SE is located in the non-display area NDA, and joins the first substrate SUB1 and the second substrate SUB2 to each other. The liquid crystal layer LC is held between the first substrate SUB1 and the second substrate SUB2. The first optical element OD1 and the liquid crystal layer LC are located on opposite sides of the first substrate SUB1; that is, they are located opposite to each other with respect to the first substrate SUB1. The second optical element OD2 and the liquid crystal layer LC are located on opposite sides of the second substrate SUB2; that is, they are located opposite to each other with respect to the second substrate SUB2. The first optical element OD1 and the second optical element OD2 each include a polarizer. It should be noted that each of the first optical element OD1 and the second optical element OD2 may include another optical element such as a retardation film.

FIG. 3 is an enlarged cross-sectional view illustrating part of the liquid crystal display panel PNL as illustrated in FIGS. 1 and 2, and also a view illustrating the first insulating substrate 10, the color filter CFR, the overcoat film OC and the inorganic film IL. The inorganic film IL includes at least one inorganic layer formed of an inorganic material. As the inorganic material, a transparent inorganic insulating material such as a silicon nitride, a silicon oxide or a silicon oxynitride can be used. In the embodiment, the inorganic film IL includes insulating layers 11 and 12 as first and second inorganic layers, respectively.

The insulating layer 11 is formed of a silicon nitride. Thus, the inorganic film IL is formed as a laminate made up of a plurality of inorganic layers including the insulating layer 11 formed of a silicon nitride. The insulating layer 11 is the lowermost one of the plurality of inorganic layers included in the inorganic film IL. The insulating layer 11 is in contact with the entire surface of the overcoat film OC, and also in the second area A2 (non-display area NDA), the insulating layer 11 is formed on the upper surface of the first insulating substrate 10 and around the first area A1. Also, in the second area A2, the insulating layer 11 is located outward of the color filter CFR.

The insulating layer 12 is formed of a silicon oxide. In the first area A1 and the second area A2, the insulating layer 12 is formed on the insulating layer 11.

As described above, it suffices that the inorganic film IL includes at least one inorganic layer. Thereby, the inorganic film IL can reduce along with the first insulating substrate 10, infiltration of water or air into the color filter CFR. It is therefore possible to reduce occurrence of a problem in the color filter CFR. For example, in a manufacturing process of the liquid crystal display device DSP, even if the color filter CFR, etc., are put in a high-temperature environment or a high-humidity environment after formation of the inorganic film IL, it is possible to reduce oxidation of the colored layers CF1, CF2 and CF3 of the color filter CFR. In this case, it is possible to reduce discoloration of the colored layers CF1, CF2 and CF3.

Furthermore, it is preferable that the inorganic film IL have at least an inorganic layer formed of a silicon nitride.

Alternatively, in the case where the inorganic film IL is formed of a single inorganic layer, it is preferable that the inorganic layer be formed of a silicon nitride.

Still alternatively, in the case where the inorganic film IL is formed as a laminate made up of a plurality of inorganic layers including an inorganic layer formed of a silicon nitride, it is preferable that the inorganic layer formed of the silicon nitride be the lowermost one of the inorganic layers included in the laminate.

In the case where in the inorganic film IL, the inorganic layer formed of the silicon nitride is not the lowermost one of the inorganic layers included in the laminate, it is preferable that in the second area A2, the inorganic layer formed of the silicon nitride be in contact with the upper surface of the first insulating substrate 10 with no space between them and formed around the first area A1.

By applying such a desired inorganic film IL as described above with respect to examples thereof, it is possible to further reduce infiltration of water or air into the color filter CFR.

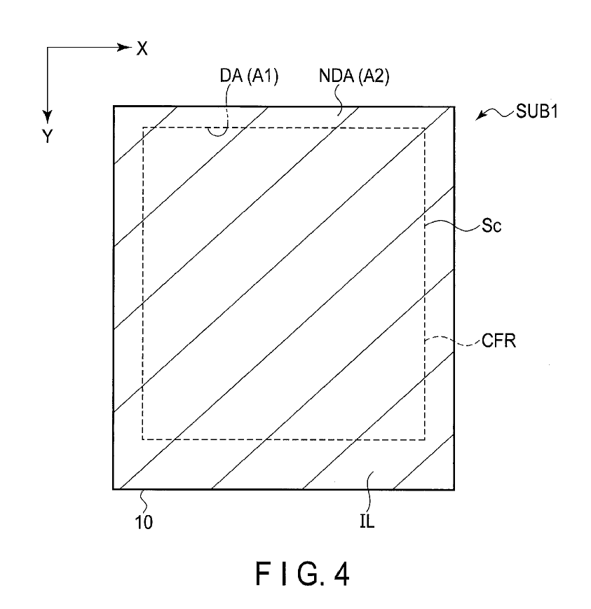

FIG. 4 is a plan view illustrating the first substrate SUB1 as illustrated in FIGS. 1 to 3 and also a view illustrating the first insulating substrate 10, the color filter CFR and the inorganic film IL. In FIG. 4, the inorganic film IL is hatched.

As illustrated in FIG. 4, as seen in plan view, the size and shape of contour of the color filter CFR correspond to those of the display area DA. In the embodiment, as seen in plan view, the shape of the display area DA is a rectangle, but it is not limited to this. That is, as seen in plan view, the shape of the display area DA may be a circle. The contour of the color filter CFR is substantially rectangular as seen in plan view. The outer peripheral surface Sc of the color filter CFR includes four side surfaces respectively corresponding to four sides of the display area DA.

As seen in plan view, the inorganic film IL is provided over the first area A1 and the second area A2. The inorganic film IL is extended to ends of the first insulating substrate 10 to have the same size as the first insulating substrate 10.

In the embodiment, the inorganic film IL is overlapped in the entire first area A1 without space, and the inorganic film IL is overlapped in the second area A2 and around the first area A1. As can be seen from the above, as seen in plan view, the inorganic film IL includes no opening. Also, as seen in plan view, the inorganic film IL is not made up of divided portions spaced from each other.

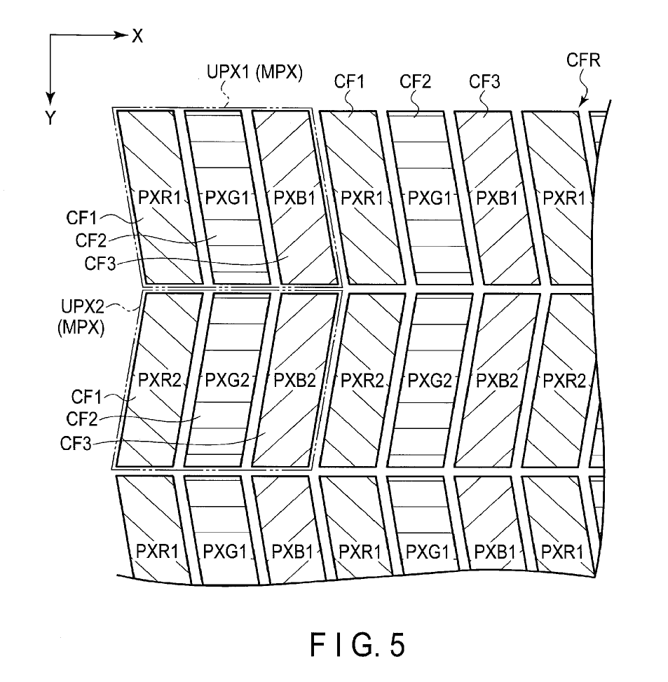

FIG. 5 is a view illustrating an example of a pixel array in the display area DA in the liquid crystal display panel PNL. FIG. 5 illustrates two kinds of unit pixels, i.e., unit pixels UPX1 and UPX2.

In such a manner, as illustrated in FIG. 5, the liquid crystal display panel PNL includes two kinds of unit pixels. That is, as the unit pixels, unit pixels UPX1 and UPX2 are provided. The unit pixels UPX1 and UPX2 are minimum unit pixels for use in displaying a color image. Each of the unit pixels UPX1 includes sub-pixels PXR1, PXG1 and PXB1. Each of the unit pixels UPX2 includes sub-pixels PXR2, PXG2 and PXB2.

The sub-pixels PXR1 and PXR2 are first-color sub-pixels, and include colored layers CF1 having a first color. The sub-pixels PXG1 and PXG2 are second-color sub-pixels, and include colored layers CF2 having a second color different from the first color. The sub-pixels PXB1 and PXB2 are third-color sub-pixels, and include colored layers CF3 having a third color different from the first and second colors. For example, the first color is red; the second color is green; and the third color is blue. The colored layers CF1 to CF3 are formed of resin materials colored to have respective colors.

However, each of the unit pixels UPX1 and UPX2 may further include a sub-pixel having a color other than red, green and blue. Alternatively, in each of the unit pixels UPX1 and UPX2, the red, green and blue sub-pixels may be replaced with sub-pixels having other colors.

In the following description, for example, light having a wavelength which falls within the range of 380 to 780 nm is defined as “visible light”. “Blue” is defined as color of light whose transmittance has a peak falling within a first wavelength range of 380 nm to less than 490 nm. “Green” is defined as color of light whose transmittance has a peak falling within a second wavelength range of 490 nm to less than 590 nm. “Red” is defined as color of light whose transmittance has a peak falling within a third wavelength range of 590 to 780 nm.

Unit pixels UPX1 are alternately arranged in the first direction X. Similarly, unit pixels UPX2 are alternately arranged in the first direction X. Furthermore, a plurality of rows of unit pixels UPX1 arranged in the first direction X and a plurality of rows of unit pixels UPX2 arranged in the first direction X are alternately arranged in the second direction Y.

The colored layers CF1 to CF3 are disposed in accordance with the layouts of the above sub-pixels, and have areas determined in accordance with the sizes of the sub-pixels. In the embodiment, the colored layers CF1 to CF3 are strip-shaped, and are arranged in the first direction X; and in each of columns of colored layers CF1 to CF3, the colored layers are arranged inclined to each other in the second direction Y.

Furthermore, the shape of each of the above sub-pixels is not limited to such an almost parallelogram as illustrated in FIG. 5. That is, it may be a square or a rectangle which is longitudinal in the second direction Y.

For example, if the shape of each of the sub-pixels is an almost parallelogram as illustrated in FIG. 5, two kinds of unit pixels, i.e., unit pixels UPX1 and UPX2, are combined, thereby also forming a large number of domains with respect to the sub-pixels having respective colors, and thus compensating for a viewing-angle characteristic. Thus, with respect to the viewing-angle characteristic, the combination of unit pixels UPX1 and UPX2 (two unit pixels) is a minimum unit in a displayed color image.

It should be noted that each of unit pixels UPX1 and UPX2 is made up of a single main pixel MPX.

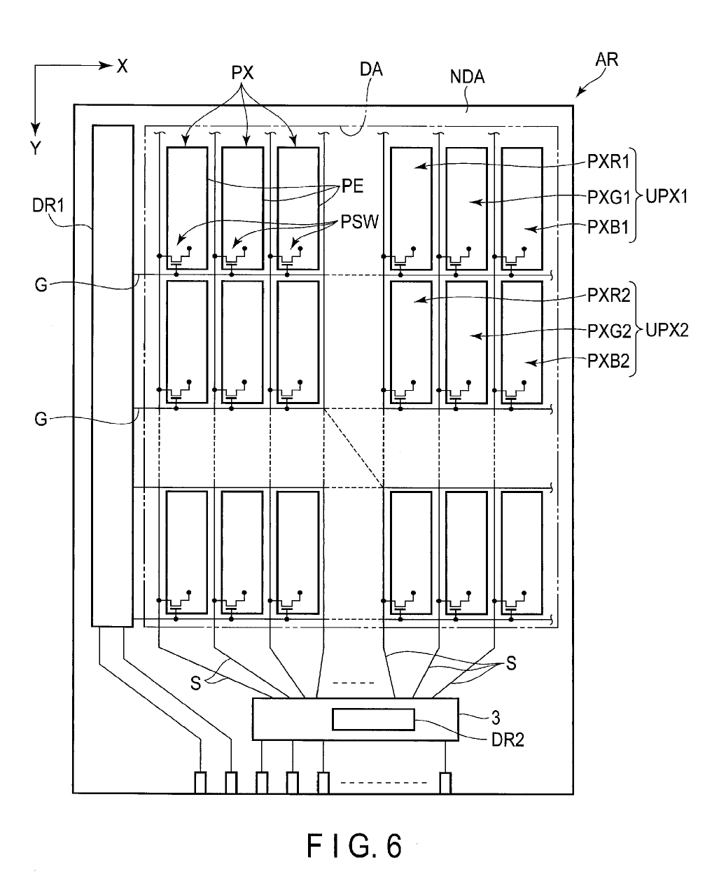

FIG. 6 is a plan view illustrating the configuration of the first substrate SUB1.

As illustrated in FIG. 6, the first substrate SUB1 comprise scanning lines G, signal lines S, pixel electrode PE, pixel switching elements PSW, a first drive circuit DR1, the driver 3, which includes a second drive circuit DR2, etc.

In the display area DA, the scanning lines G extend in the first direction X, and are arranged and spaced from each other in the second direction Y. In the embodiment, the scanning lines G linearly extend in the first direction X. Also, in the display area DA, the signal lines S extend in the second direction Y, intersect the scanning lines G, and are arranged and spaced from each other in the first direction X. It should be noted that the signal lines S need not always linearly extend; i.e., they may be partially bent or extend in a direction intersecting the first direction X and the second direction Y. In each sub-pixel PX, an associated pixel electrode PE and an associated pixel switching element PSW are provided. The pixel switching element PSW is electrically connected to an associated scanning line G and an associated signal line S. The pixel electrode PE is electrically connected to the pixel switching element PSW.

In the example illustrated in FIG. 6, to each unit pixel UPX1 including three sub-pixels PXR1, PXG1 and PXB1, associated three signal lines S and an associated single scanning line G are assigned. Also, to each unit pixel UPX2 including three sub-pixels PXR2, PXG2 and PXB2, associated three signal lines S and an associated single scanning line G are assigned.

The first drive circuit DR1 and the second drive circuit DR2 are located in the non-display area NDA. The first drive circuit DR1 is electrically connected to portions of the scanning lines G which are located in the non-display area NDA. The second drive circuit DR2 is electrically connected to portions of the signal lines S which are located in the non-display area NDA. The first drive circuit DR1 supplies a control signal to each of the scanning lines G. The second drive circuit DR2 supplies an image signal (for example, a video signal) to each of the signal lines S.

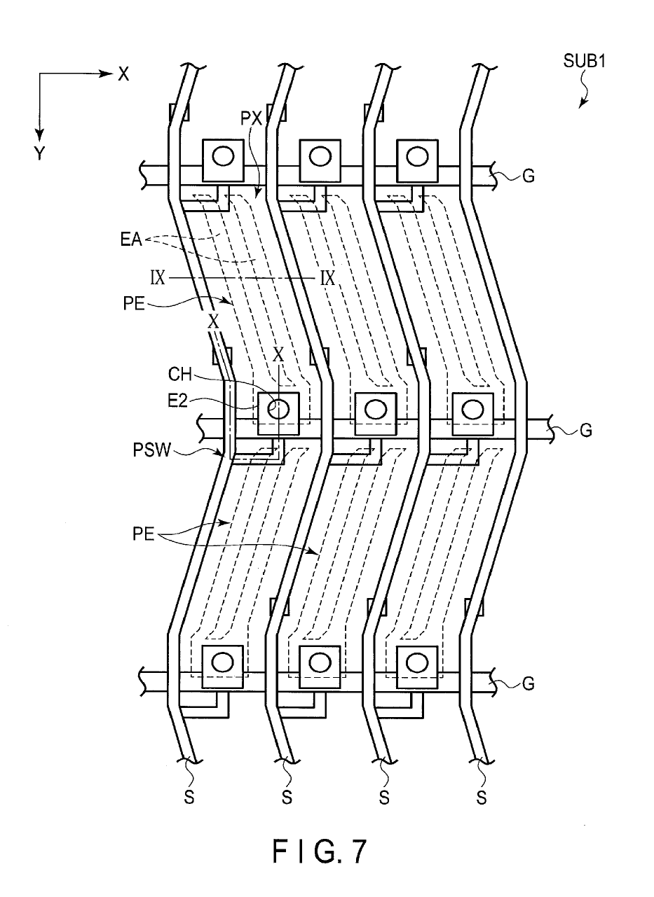

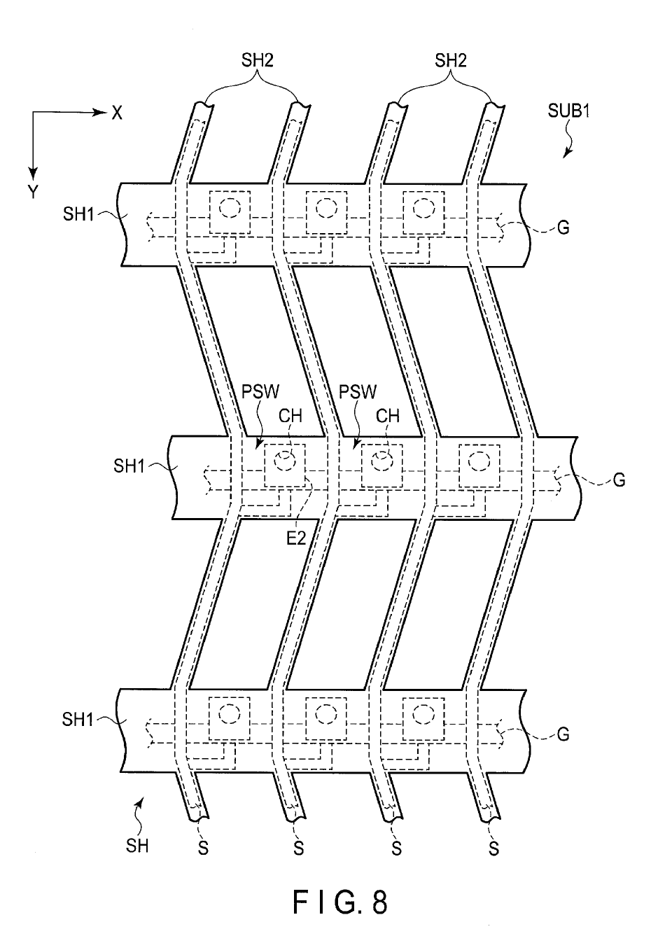

FIG. 7 is an enlarged plan view illustrating part of the first substrate SUB1, and illustrates scanning lines G, signal lines S, pixel switching elements PSW, second electrodes E2, contact holes CH and pixel electrodes PE. It should be noted that FIG. 7 illustrates only structural elements which need to be referred to in explanations to be given below, and omits the color filter CFR, the inorganic film IL, etc.

As illustrated in FIG. 7, a plurality of scanning lines G linearly extend in the first direction X. It should be noted that the scanning lines G need not always linearly extend; i.e., they may be partially bent. A plurality of signal lines S extend substantially in the second direction Y, and partially bent. In the example illustrated in FIG. 7, between any adjacent two of the scanning lines G, signal lines S extend in a direction other than the first direction X and the second direction Y. It should be noted that the signal lines S may be linearly extended in the second direction Y. In FIG. 7, each of sub-pixels PX corresponds to a region defined by associated two adjacent scanning lines G and associated two adjacent signal lines S.

The pixel switching element PSW is electrically connected to an associated scanning line G and an associated signal line S. The pixel switching element PSW will be described later in detail. The second electrodes E2 are electrically connected to the pixel switching elements PSW, respectively. The pixel electrodes PE, as indicated by dashed lines in FIG. 7, are provided in the sub-pixels PX, respectively. The pixel electrodes PE are electrically connected to the second electrodes E2, respectively. In the example illustrated in FIG. 7, each of the pixel electrodes PE includes two strip-shaped electrodes EA. The strip-shaped electrodes EA extend substantially parallel to associated signal lines S which are adjacent to each other in the first direction X. As seen in plan view, each of the contact holes CH is superimposed on both an associated second electrode E2 and an associated pixel electrode PE. Each contact holes CH is used to connect the pixel electrode PE to the second electrode E2.

FIG. 8 is an enlarged plan view illustrating part of the first substrate SUB1, and illustrates the light-shielding layer SH, scanning lines G, signal lines S, pixel switching elements PSW, second electrodes E2 and contact holes CH. In FIG. 8, only the light-shielding layer SH is indicated by a solid line.

As illustrated in FIG. 8, the first substrate SUB1 includes the light-shielding layer SH. The light-shielding layer SH is made up of a plurality of first light-shielding portions SH1 and a plurality of second light-shielding portions SH2; that is, the first light-shielding portions SH1 and the second light-shielding portions SH2 are made integral with each other to form the light-shielding layer SH. The light-shielding layer SH is formed in such a way as to define the sub-pixels PX.

The first light-shielding portions SH1, as seen in plan view, extend along the scanning lines G, and are superimposed on the scanning lines G. In the embodiment, the first light-shielding portions SH1 are strip-shaped, and are superimposed on the scanning lines G, pixel switching elements PSW arranged in the first direction X and second electrodes E2 arranged in the first direction X, as seen in plan view.

The second light-shielding portions SH2, as seen in plan view, extend along the signal lines S, and are superimposed on the signal lines S.

The light-shielding layer SH has a function of blocking light emitted at least from the backlight unit BL. The light-shielding layer SH is formed of material having a high optical absorptance, such as black resin. Alternatively, the light-shielding layer SH is formed of material having a high optical reflectivity, such as metal.

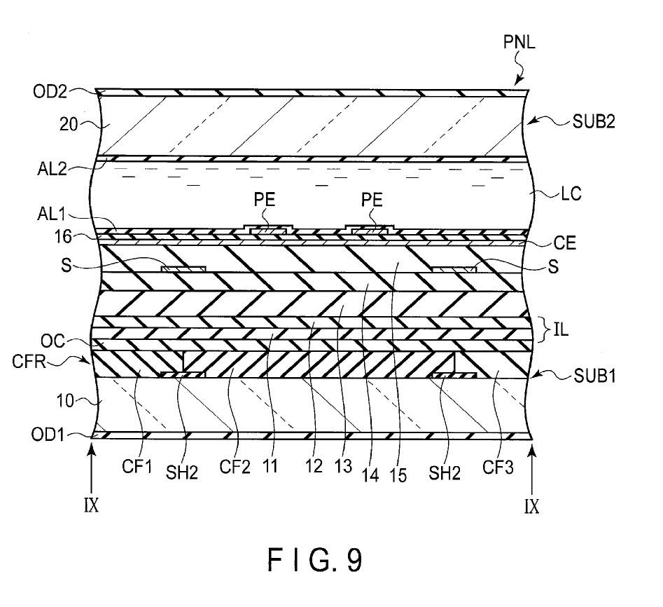

FIG. 9 is a cross-sectional view of the liquid crystal display panel PNL which is taken along line IX-IX in FIG. 7.

As illustrated in FIG. 9, the first substrate SUB1 comprises the first insulating substrate 10, the color filter CFR, the insulating layers 11, 12, 13, 14, 15 and 16, the signal lines S, a common electrode CE, the pixel electrodes PE, an alignment film AL1, etc.

The insulating layers 11 to 16 are all transparent. The insulating layers 11 to 14 and 16 are inorganic insulating layers. For example, the insulating layers 13, 14 and 16 are formed of a silicon nitride and a silicon oxide. The insulating layer 15 is a transparent organic insulating layer, and for example, it is formed of resin such as acrylic resin. The insulating layer 11 is located above the first insulating substrate 10 and the color filter CFR. The insulating layer 12 is formed on the insulating layer 11. The insulating layer 13 is formed on the insulating layer 12. The insulating layer 14 is formed on the insulating layer 13.

The signal lines S are formed on the insulating layer 14. An adjacency between colored layers CF1 and CF2 and that between colored layers CF2 and CF3 are located under respective signal lines S.

The insulating layer 15 is located on the insulating layer 14 and the signal lines S.

The common electrode CE is located on the insulating layer 15. The common electrode CE extends over a plurality of sub-pixels. In the example illustrated in FIG. 9, the common electrode CE extends such that it is located above the signal lines S and on the insulating layer 15.

The insulating layer 16 is located on the common electrode CE.

The pixel electrodes PE are located on the insulating layer 16. The pixel electrodes PE are provided in the sub-pixels, respectively.

The alignment film AL1 covers the insulating layer 16 and the pixel electrodes PE.

A liquid crystal layer LC is provided on the first substrate SUB1. The liquid crystal layer LC may be formed of a positive liquid crystal material having a positive dielectric anisotropy or a negative liquid crystal material having a negative dielectric anisotropy.

The second substrate SUB2 is located on the liquid crystal layer LC. The second substrate SUB2 comprises a second insulating substrate 20, an alignment film AL2, etc. The second insulating substrate 20 is formed of a transparent insulating material. For example, it is formed of glass which is an inorganic material, such as borosilicate glass. In the embodiment, the second insulating substrate 20 is a glass substrate formed of glass. The alignment film AL2 is formed under the second insulating substrate 20.

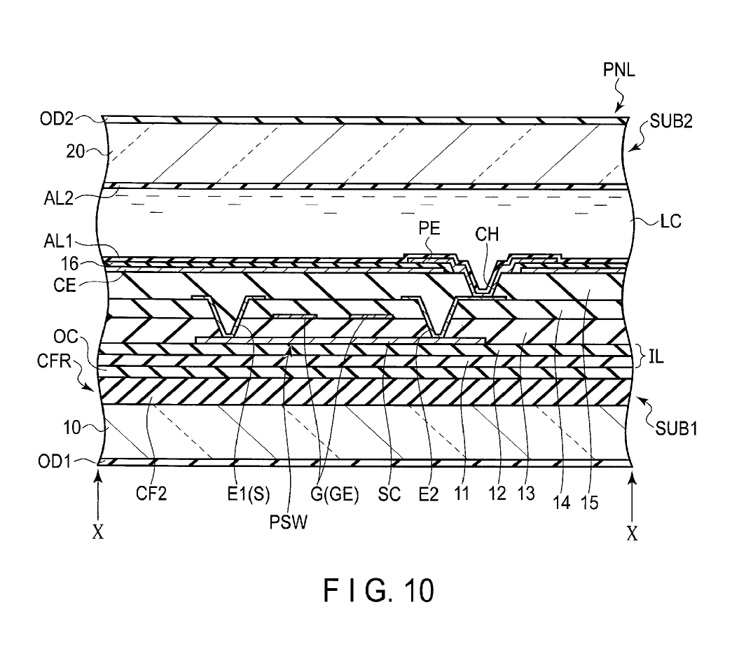

FIG. 10 is a cross-sectional view of the liquid crystal display panel PNL which is taken along line X-X in FIG. 7. The following explanation is given mainly with respect to structural elements different from those illustrated in the cross-sectional view of FIG. 9.

Referring to FIG. 10, which illustrates part of the first substrate SUB1, a pixel switching element PSW is provided in the first substrate SUB1. The pixel switching element PSW includes a semiconductor layer SC. The semiconductor layer SC is located between the insulating layers 12 and 13.

The semiconductor layer SC is formed of polycrystalline silicon (poly-Si); however, it may be formed of amorphous silicon, an oxide semiconductor or the like. As the oxide semiconductor, an oxide containing at least one of indium, gallium and zinc is proper. Typical examples of the oxide semiconductor are an indium gallium zinc oxide (IGZO), an indium gallium oxide (IGO), an indium zinc oxide (IZO), a zinc tin oxide (ZnSnO), a zinc oxide (ZnO), a transparent amorphous oxide semiconductor (TAOS), etc.

In view of an influence of heat upon the color filter CFR, it is preferable that the semiconductor layer SC be formed of an oxide semiconductor. This is because in the case where the semiconductor layer SC is formed of an oxide semiconductor, it can be formed in a low-temperature environment, as compared with the case where it is formed of poly-Si.

Two gate electrodes GE corresponding to part of scanning lines G are located between the insulating layers 13 and 14. The scanning lines G are formed of metallic material, for example, a molybdenum tungsten alloy. A first electrode E1 and a second electrode E2 are located between the insulating layers 14 and 15. The first electrode E1 and signal line S are formed as a single body. The first electrode E1 (signal line S) and the second electrode E2 are formed of metallic material. For example, the first electrode (signal line S) and the second electrode E2 are formed of metals, i.e., titanium, aluminum and titanium which are stacked in this order.

The first electrode E1 is in contact with a first region of the semiconductor layer SC through a contact hole formed in the insulating layers 13 and 14. The second electrodes E2 is in contact with a second region of the semiconductor layer SC through another contact hole formed in the insulating layers 13 and 14. In the case where the first electrode E1 and the second electrodes E2 function as a source electrode and a drain electrode, respectively, the first region and second region of the semiconductor layer SC function as a source region and a drain region, respectively. Alternatively, in the case where the first electrode E1 and the second electrodes E2 function as a drain electrode and a source electrode, respectively, the first region and second region of the semiconductor layer SC function as a drain region and a source region, respectively.

In the embodiment, the pixel switching elements PSW are each formed of a top-gate thin-film transistor. However, each pixel switching element PSW may be formed of a bottom-gate thin-film transistor.

Furthermore, in the embodiment, each pixel switching element PSW has a double-gate structure. However, each pixel switching element PSW may have a single-gate structure.

Referring to FIG. 10, the pixel electrode PE is in contact with the second electrode E2 through a contact hole CH formed in the insulating layer 15 and a contact hole formed in the insulating layer 16.

The common electrode CE and the pixel electrode PE are formed of transparent conductive material such as indium tin oxide (ITO), an indium zinc oxide (IZO) or a zinc oxide (ZnO).

In the above first substrate SUB1, each of pixels having different colors includes a pixel electrode PE and any of the colored layers CF1 to CF3. Furthermore, between the pixel electrodes PE and the color filter CFR, the liquid crystal layer LC is not located. Thus, the pixel electrodes PE and the color filter CFR are closer to each other. It is therefore possible to prevent color mixing.

According to the liquid crystal display device DSP of the embodiment, the liquid crystal display panel PNL comprises the color filter CFR, the inorganic film IL and the semiconductor layer SC. The color filter CFR is formed on the first insulating substrate 10. The inorganic film IL is formed above the color filter CFR. The semiconductor layer SC is formed above the inorganic film IL. As seen in plan view, the inorganic film IL is provided over the first area A1 in which the color filter CFR is located and the second area A2 which surrounds the first area A1. In the second area A2, the inorganic film IL is formed on the upper surface of the first insulating substrate 10 (the upper surface of an inorganic layer) and around the first area A1. Also, in the second area A2, the inorganic film IL is located outward of the color filter CFR.

The inorganic film IL can reduce along with the first insulating substrate 10, infiltration of water or air into the color filter CFR, and reduce oxidation of the colored layers CF1, CF2 and CF3. Thus, since discoloration of the colored layers CF1, CF2 and CF3 can be reduced, the liquid crystal display panel PNL can be formed to have a high color purity. It is therefore possible to obtain a liquid crystal display panel PNL in which colored layers CF1, CF2 and CF3 will not easily be discolored for a long time period after manufacturing of the liquid crystal display panel PNL.

Furthermore, the liquid crystal display panel PNL further comprises the pixel switching elements PSW, the insulating layer 15, the contact holes CH and the pixel electrodes PE. The pixel switching elements PSW include the semiconductor layers SC, respectively. The insulating layer 15 is located above the pixel switching elements PSW, and formed of organic material. In the insulating layer 15, the contact holes CH are formed. Each of the pixel electrodes PE is formed above the insulating layer 15, and connected to an associated pixel switching element PSW through an associated contact hole CH.

As described above, according to the embodiment, the color filter CFR is located below the pixel switching elements PSW; i.e., it is not located above the pixel switching elements PSW. That is, the contact holes CH are formed in the insulating layer 15, and does not need to be formed in the colored layers CF1, CF2 and CF3.

For example, the insulating layer 15 can be thinner than the colored layers CF1, CF2 and CF3, and in this case, as seen in plan view, the sizes of the contact holes CH can be reduced.

Furthermore, unlike the colored layers CF1, CF2 and CF3, the insulating layer 15 is formed of transparent resin. Thus, in exposure, light is easily transmitted through the insulating layer 15, and the resin of the insulating layer 15 is easily changed in quality. This also enables the contact holes CH to be made smaller in size, as seen in plan view.

In each of portions of the liquid crystal layer LC which are located above the contact holes CH, it is possible to reduce a region in which an alignment failure occurs. Thereby, it is possible to reduce leakage of light which would be caused by an alignment failure, and thus obtain a liquid crystal display panel PNL having a high contrast ratio.

In addition, the color filter CFR is provided in the first substrate SUB1, not in the second substrate SUB2. Thus, according to the embodiment, in even a high-definition liquid crystal display panel PNL, it is possible to reduce occurrence of color mixing, while reducing lowering of an aperture ratio.

By virtue of the above advantages, it is possible to obtain a liquid crystal display device DSP having a high display quality.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

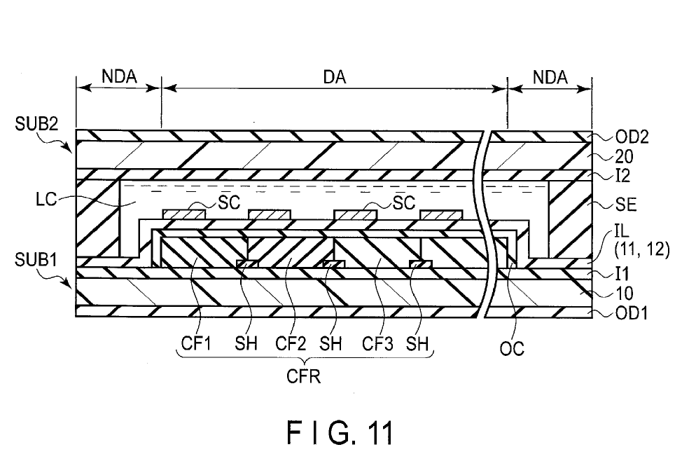

For example, as illustrated in FIG. 11, the first insulating substrate 10 may be formed of resin such as plastic, which is an organic material. In this case (a modification of the embodiment), the second insulating substrate 20 is also formed of resin such as plastic, which is an organic material.

An inorganic film I1 is formed on the first insulating substrate 10 and covers the first insulating substrate 10. The inorganic film I1 is formed as a single inorganic layer or a laminate made up of a plurality of inorganic layers. In the modification, an upper surface of the inorganic film I1 functions as an upper surface of an inorganic layer. The color filter CFR is formed on an upper surface of the inorganic film I1. In the second area A2, the inorganic film IL is in contact with the upper surface of the inorganic film I1 with no space between them and formed around the first area A1.

Furthermore, an inorganic film 12 is formed under the second insulating substrate 20 and covers the second insulating substrate 20. The inorganic film 12 is formed as a single inorganic layer or a laminate made up of a plurality of inorganic layers.

Also, in the above modification, the inorganic film IL can reduce along with the inorganic film I1, infiltration of water or air into the color filter CFR. Thus, the modification can obtain the same advantages as the embodiment.

In addition, according to the embodiment, the liquid crystal display panel PNL adopts an FFS mode. However, the display mode of the liquid crystal display panel is not limited to this; that is, the liquid crystal panel PNL may adopt another display mode.

The embodiment is not limited to the liquid crystal display device DSP; that is, it can be applied to various kinds of liquid crystal display devices.

What is claimed is:

1. A display device comprising:
a color filter formed on an inorganic layer;
an inorganic film formed above the color filter; and
a semiconductor layer formed above the inorganic film,
wherein
as seen in plan view, the inorganic film is provided over a first area in which the color filter is overlapped and a second area which surrounds the first area, and
in the second area, the inorganic film is located outward of the color filter.

2. The display device of claim 1, wherein
the inorganic film includes a first inorganic layer formed of a silicon nitride.

3. The display device of claim 1, wherein
the inorganic film is formed as a laminate made up of a plurality of inorganic layers including a first inorganic layer formed of a silicon nitride.

4. The display device of claim 3, wherein
the first inorganic layer is a lowermost one of the inorganic layers.

5. The display device of claim 1, further comprising:
an insulating substrate which is located under the color filter and formed of a glass,
wherein
an upper surface of the inorganic layer is an upper surface of the insulating substrate.

6. The display device of claim 1, further comprising:
a pixel switching element including the semiconductor layer;
an insulating layer located above the pixel switching element and formed of an organic material;
a contact hole formed in the insulating layer; and
a pixel electrode formed above the insulating layer and connected to the pixel switching element through the contact hole.

7. The display device of claim 1, further comprising:
a first substrate including the color filter, the inorganic film and the semiconductor layer;
a second substrate located above the first substrate and opposite to the first substrate with a gap between the first substrate and second substrate; and
a liquid crystal layer held between the first substrate and second substrate.
